(19) United States
(12) Patent Application Publication
(10) Pub. No.: US 2012/0056266 A1
(43) Pub. Date: Mar. 8, 2012

(54) SEMICONDUCTOR DEVICE AND MANUFACTURING METHOD THEREOF

(75) Inventors: Keita UCHIYAMA, Toyama (JP); Kenji Yoneda, Toyama (JP)

(73) Assignee: Panasonic Corporation, Osaka (JP)

(21) Appl. No.: 13/293,603

(22) Filed: Nov. 10, 2011

Related U.S. Application Data
(63) Continuation of application No. PCT/JP2009/007059, filed on Dec. 21, 2009.

(30) Foreign Application Priority Data
Jun. 24, 2009 (JP) 2009-149242

(51) Int. Cl. H01L 27/092; H01L 21/28

(52) U.S. Cl. 257/368; 438/591; 257/411; 257/E27.062; 257/E21.19

(57) ABSTRACT

A semiconductor device includes a plurality of gate insulating films formed on a semiconductor substrate. Of the plurality of gate insulating films, the gate insulating film having a smallest thickness in an HP transistor formation region is a silicon oxide film, and each of the remaining gate insulating films in an I/O transistor formation region and an LP transistor formation region is a silicon oxynitride film.

### CROSS-REFERENCE TO RELATED APPLICATION

This is a continuation of PCT International Application PCT/JP2009/007059 filed on Dec. 21, 2009, which claims priority to Japanese Patent Application No. 2009-149242 filed on Jun. 24, 2009. The disclosures of these applications including the specifications, the drawings, and the claims are hereby incorporated by reference in their entirety.

### BACKGROUND

The technique disclosed in the present invention relates to semiconductor devices and manufacturing methods thereof, and more particularly to semiconductor devices having a structure corresponding to a plurality of types of power supplies.

In semiconductor devices, high performance transistors (hereinafter referred to as the “HP transistors”) designed particularly for high speed performance are used in a core section, which is a section provided with a circuit configured to perform a high-speed logical operation. Such HP transistors are designed to have a gate insulating film having a smaller thickness than gate insulating films of transistors in other sections and to have a lower threshold voltage than the transistors in the other sections. The HP transistor is structured to reduce a gate leakage current that increases as the thickness of the gate insulating film decreases, and an off-state current that increases as the threshold voltage decreases, so that in order to preferentially secure an on-state current that determines the operating speed of the transistor.

Transistors (hereinafter referred to as the “I/O transistors”) designed particularly for a higher gate breakdown voltage are used in an input/output (I/O) section, which is a section provided with a circuit configured to receive and output data from and to another semiconductor device. Such I/O transistors are designed to have a gate insulating film having a larger thickness than the gate insulating films of the transistors in the other sections, and to have a higher threshold voltage than the HP transistors in the core section.

Low power transistors (LP transistors) are used in a low power section, which is a section provided with a circuit whose leakage current need be reduced as much as possible in order to reduce, e.g., standby power consumption. Such LP transistors are designed to have a gate insulating film having a thickness between the thickness of the gate insulating film in the core section and the thickness of the gate insulating film in the I/O section, thereby reducing the gate leakage current.

As described above, several types of transistors are formed on the same substrate according to the required performance. This requires a plurality of gate insulating films having different thicknesses to be formed on the same substrate.

A silicon oxynitride film, which is formed by introducing nitrogen into a silicon oxide film by plasma nitridation, is typically used as the gate insulating film. Silicon oxynitride films as a plurality of gate insulating films are formed on the same substrate by repeatedly removing a silicon oxide film to form silicon oxide films having a plurality of thicknesses, and then performing plasma nitridation on the silicon oxide films.

Specifically, a conventional semiconductor device having silicon oxynitride films as gate insulating films having two or more different thicknesses on the same semiconductor substrate, and a manufacturing method thereof will be described with reference to the accompanying drawings.

As shown in FIG. 5A, an element isolation region 102 is first formed in a silicon substrate 101 to define regions on the silicon substrate 101, thereby forming an I/O transistor formation region 100A, an LP transistor formation region 100B, and an HP transistor formation region 100C.

As shown in FIG. 5B, the silicon substrate 101 is then subjected to thermal oxidation to oxidize the surface of the silicon substrate 101. Thus, a silicon oxide film 103 having a thickness of 5-8 nm is formed in the I/O transistor formation region 100A, the LP transistor formation region 100B, and the HP transistor formation region 100C.

As shown in FIG. 5C, a resist pattern 104, which has an opening that exposes the surface of the silicon substrate 101 in the LP transistor formation region 100B, is formed on the silicon oxide film 103 by using photolithography and etching techniques. Then, the silicon oxide film 103 in the LP transistor formation region 100B is etched away by using the resist pattern 104 as a mask.

As shown in FIG. 5D, after the resist pattern 104 has been removed, thermal oxidation is performed to form a silicon oxide film 105 having a thickness of 2-5 nm on the surface of the silicon substrate 101 in the LP transistor formation region 100B.

As shown in FIG. 6A, a resist pattern 106 is formed which has an opening that exposes the surface of the silicon substrate 101 in the HP transistor formation region 100C. Then, the silicon oxide film 103 in the HP transistor formation region 100C is etched away by using the resist pattern 104 as a mask.

As shown in FIG. 6B, after the resist pattern 106 has been removed, thermal oxidation is performed to form a silicon oxide film 107 having a thickness of 1-2 nm on the surface of the silicon substrate 101 in the HP transistor formation region 100C.

As shown in FIG. 6C, plasma nitridation is performed on the silicon oxide films 103, 105, and 107. In this plasma nitridation, the silicon oxide films 103, 105, and 107 are nitrided from their top surfaces to form silicon oxynitride films 108, 109, and 110 in the I/O transistor formation region 100A, the LP transistor formation region 100B, and the HP transistor formation region 100C, respectively.

As shown in FIG. 6D, gate polysilicon is grown on the silicon oxynitride films 108, 109, and 110 to form a gate polysilicon electrode 112.

A semiconductor device having gate insulating films having two or more different thicknesses on the same substrate is manufactured in this manner.

### SUMMARY

The gate insulating film in the HP transistor in the core section has a smaller thickness than the gate insulating films in the I/O transistor and the LP transistor. Thus, if a large amount of nitrogen is introduced into the silicon oxide film in the plasma nitridation, a large amount of nitrogen reaches the interface between the silicon oxide film and the silicon substrate in the HP transistor formation region. As a result, a silicon nitride film is formed at the interface, increasing the physical thickness of the gate insulating film. If the physical thickness of the gate insulating film is significantly increased, an equivalent oxide thickness thereof is increased accordingly even if the dielectric constant of the insulating film is increased. Moreover, many defects are produced at the interface between the silicon oxide film and the silicon substrate, whereby carrier mobility is reduced, and transistor performance is degraded. Note that as used herein, the “equivalent oxide thickness” refers to an electrical thickness of the gate insulating film calculated as a thickness of an oxide film in view of an increase in dielectric constant due to the introduction of nitrogen.

FIG. 7 is a graph showing the relation between the plasma nitridation time (abscissa) and the equivalent oxide thickness (ordinate) of the gate insulating film.

As shown in FIG. 7, as the plasma nitridation time increases, nitrogen reaches the interface between the oxide film and the substrate, and in a region 2a, the physical thickness increases, and the equivalent oxide thickness increases accordingly, whereby the transistor performance is degraded. Thus, it is not preferable to perform the plasma nitridation for a long time, and the plasma nitridation time need be relatively short.

On the other hand, in the I/O transistor and the LP transistor designed particularly for a higher gate breakdown voltage or a lower gate leakage current, it is preferable to reduce the equivalent oxide thickness while increasing the physical thickness by introducing as much nitrogen as possible to increase the dielectric constant.

In recent years, an ultrathin gate insulating film as thin as around 1 nm has been demanded for the HP transistors in the core section in order to address the need for a higher operating speed. In this case, an initial silicon oxide film before plasma nitridation has a thickness of around 1 nm. Accordingly, even if a small amount of nitrogen is introduced by the plasma nitridation, a large amount of nitrogen reaches the interface between the silicon oxide film and the silicon substrate, thereby degrading the transistor performance.

That is, in the I/O and LP transistors having thicker gate insulating films, it is desired to introduce a large amount of nitrogen into the gate insulating film in order to increase the gate breakdown voltage of the gate insulating film and to reduce the gate leakage current. In this case, however, a large amount of nitrogen reaches the interface between the silicon oxide film and the substrate in the HP transistor having the thinnest gate insulating film, thereby degrading the performance of the HP transistor.

As a solution to this problem, in a technique proposed in Japanese Patent Publication No. 2002-368122, a silicon oxynitride film formed by thermal oxynitridation using nitrogen monoxide, rather than the silicon oxide film, is used as an initial insulating film before plasma nitridation to form the gate insulating film of the HP transistor having the smallest thickness. Thus, nitrogen in the silicon oxynitride film blocks nitrogen introduced by the plasma nitridation so that the introduced nitrogen does not reach the interface with the substrate.

In view of the above problems, it is an object of the present invention to ensure high speed performance of, e.g., an HP transistor in a core section while achieving an increased gate breakdown voltage and a reduced gate leakage current of, e.g., an I/O transistor and an LP transistor, in a semiconductor device having a plurality of gate insulating films on the same substrate and a manufacturing method thereof. It is another object of the present invention to provide a technique capable of reducing the thickness of a gate insulating film of an HP transistor to 1 nm or less in a semiconductor device having a plurality of gate insulating films on the same substrate and a manufacturing method thereof.

In order to achieve the above objects, the present invention provides an example semiconductor device and a manufacturing method thereof as described below.

A semiconductor device according to the present invention includes a plurality of gate insulating films formed on a semiconductor substrate. One of the plurality of gate insulating films having a smallest thickness is a first stacked film that is formed by sequentially stacking, from bottom to top, a silicon oxide film and an insulating film having a higher dielectric constant than the silicon oxide film, and each of the plurality of gate insulating films other than the one having the smallest thickness is a second stacked film formed by sequentially stacking, from bottom to top, a silicon oxynitride film and an insulating film having a higher dielectric constant than the silicon oxide film and the silicon oxynitride film. The semiconductor device further includes a metal gate electrode formed on the first stacked film and the second stacked film.

It is preferable that the above semiconductor device further include a cap film formed between the first and second stacked films and the metal gate electrode.

It is preferable that the above semiconductor device further include a polysilicon electrode formed on the metal gate electrode.

It is preferable that in the above semiconductor device, the insulating film having the higher dielectric constant than the silicon oxide film be a metal oxide film comprised of aluminum oxide, lanthanum oxide, hafnium oxide, or zirconium oxide, or a metal silicate film comprised of aluminum silicate, lanthanum silicate, hafnium silicate, or zirconium silicate.

It is preferable that in the above semiconductor device, the semiconductor substrate be divided into a first semiconductor region where a high performance transistor is formed, a second semiconductor region where an I/O transistor is formed, and a third semiconductor region where a low power transistor is formed, that the plurality of gate insulating films be three gate insulating films corresponding to the first to third semiconductor regions, that of the three gate insulating films, the gate insulating film corresponding to the first semiconductor region have a smaller thickness than the gate insulating film corresponding to the second semiconductor region and the gate insulating film corresponding to the third semiconductor region, and that the gate insulating film corresponding to the second semiconductor region have a thickness equal to or larger than that of the gate insulating film corresponding to the third semiconductor region.

A method for manufacturing a semiconductor device according to the present invention includes the steps of: (a) forming a plurality of silicon oxide films on a semiconductor substrate; (b) introducing nitrogen into the plurality of silicon oxide films to form a plurality of silicon oxynitride films; (c) removing one of the plurality of silicon oxynitride films having a smallest thickness; (d) forming a silicon oxide film in a portion where the silicon oxynitride film having the smallest thickness has been removed in the step (c); (e) after the step (d), forming an insulating film having a higher dielectric constant than the silicon oxide films and the silicon oxynitride films, on each of the plurality of silicon oxynitride films remaining after removing the silicon oxynitride film having the smallest thickness, and on the silicon oxide film formed in the step (d); and (f) forming a metal gate electrode on the insulating film having the higher dielectric constant than the silicon oxide films and the silicon oxynitride films.

It is preferable that the above method further include the step of (g) forming a polysilicon electrode on the metal gate electrode.

It is preferable that in the step (b) of the above method, the nitrogen be introduced by plasma nitridation, or thermal nitridation using a gas of nitrogen monoxide, nitrogen dioxide, or ammonia.

It is preferable that in the step (e) of the above method, the insulating film having the higher dielectric constant than the silicon oxide film be formed by an ALD method, a CVD method, or a PVD method.

According to the above example semiconductor device of the present invention and the above manufacturing method thereof, in a semiconductor device having a plurality of gate insulating films on the same substrate, high speed performance of, e.g., an HP transistor in a core section can be ensured while achieving an increased gate breakdown voltage and a reduced gate leakage current in, e.g., an I/O transistor and an LP transistor. Moreover, in, e.g., the HP transistor in the core section, an ultrathin gate insulating film as thin as 0.5-2 nm can be obtained only by a silicon oxide film without performing plasma nitridation. This enables the HP transistor in the core section to have a gate insulating film as thin as 1 nm or less so as to meet the need for a higher operating speed of the HP transistor.

### BRIEF DESCRIPTION OF THE DRAWINGS

FIGS. 1A-1D are cross-sectional views sequentially illustrating the steps of a manufacturing method of a semiconductor device according to a first example embodiment of the present invention.

FIGS. 2A-2D are cross-sectional views sequentially illustrating the steps of the manufacturing method of the semiconductor device according to the first example embodiment of the present invention.

FIGS. 3A-3E are cross-sectional views sequentially illustrating the steps of a manufacturing method of a semiconductor device according to a second example embodiment of the present invention.

FIGS. 4A-4D are cross-sectional views sequentially illustrating the steps of the manufacturing method of the semiconductor device according to the second example embodiment of the present invention.

FIGS. 5A-5D are cross-sectional views sequentially illustrating the steps of a manufacturing method of a conventional semiconductor device.

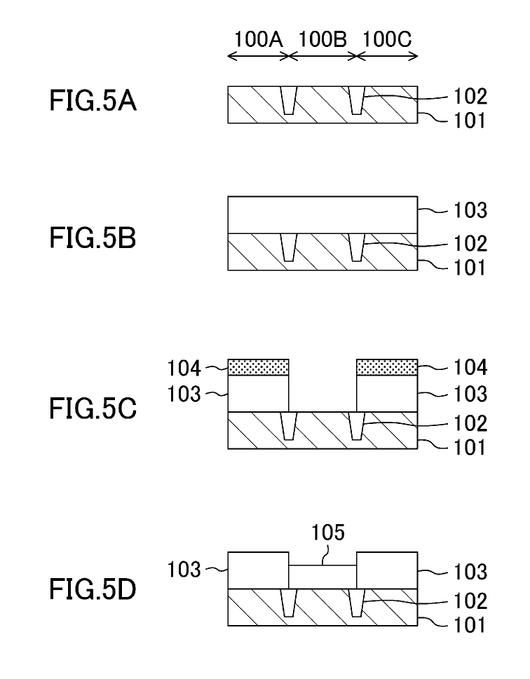

FIGS. 6A-6D are cross-sectional views sequentially illustrating the steps of the manufacturing method of the conventional semiconductor device.

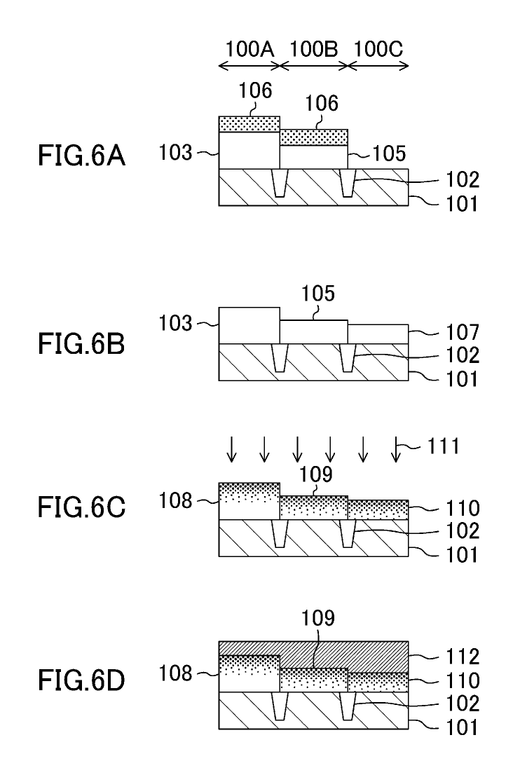

FIG. 7 is a graph showing the relation between the plasma nitridation time and the equivalent oxide thickness of a gate insulating film.

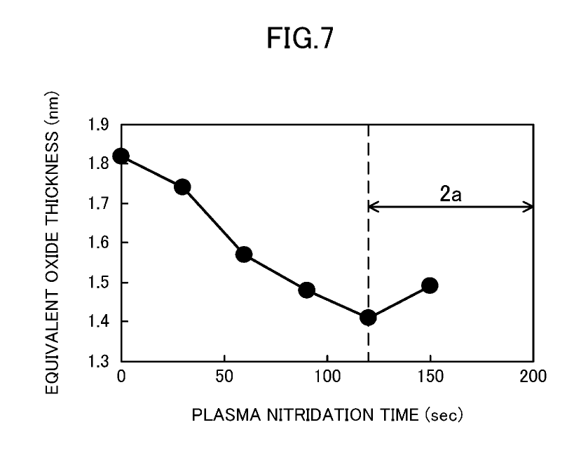

### DETAILED DESCRIPTION

In the following detailed description together with the accompanying drawings, embodiments of the invention are described in sufficient detail to enable those having ordinary skill in the art to practice the invention. It is to be understood that other embodiments may be used, and changes may be made, without departing from the spirit or scope of the present invention. The following detailed description is, therefore, not to be taken in a limiting sense, and the scope of the present invention is defined only by the appended claims. A plurality of embodiments described below may be combined without departing from the scope of the present invention.

A semiconductor device having silicon oxynitride films as gate insulating films having two or more different thicknesses on the same semiconductor substrate, and a manufacturing method thereof according to each example embodiment of the present invention will be described below.

Specifically, an example embodiment is described where a semiconductor substrate has an HP transistor formation region (a first semiconductor region) in a core section, which is a section provided with a circuit configured to perform a high-speed logical operation, an I/O transistor formation region (a second semiconductor region) in an I/O section, which is a section provided with a circuit configured to receive and output data from and to another semiconductor device, and an LP transistor formation region (a third semiconductor region) in a low power section, which is a section provided with a circuit whose leakage current need be reduced as much as possible in order to reduce, e.g., standby power consumption, and high performance transistors (HP transistors) designed particularly for high speed performance are formed in the HP transistor formation region, transistors (I/O transistors) designed particularly for a higher gate breakdown voltage are formed in the I/O transistor formation region, and low power transistors (LP transistors) are formed in the LP transistor formation region. However, the present invention is not limited to this example, and is applicable to a structure in which the semiconductor device includes gate insulating films having a plurality of different thicknesses in each of the HP transistor formation region, the I/O transistor formation region, and the LP transistor formation region.

### First Embodiment

A semiconductor device and a manufacturing method according to a first example embodiment of the present invention will be described below with reference to the accompanying drawings.

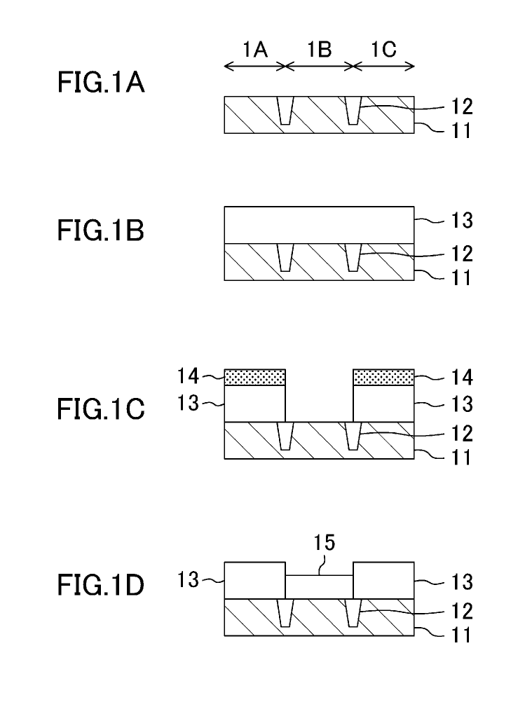

As shown in FIG. 1A, an element isolation region 12 is first formed in a silicon substrate 11 to define regions on the silicon substrate 11, thereby forming an I/O transistor formation region 1A, an LP transistor formation region 1B, and an HP transistor formation region 1C.

As shown in FIG. 1B, the silicon substrate 11 is then subjected to thermal oxidation to oxidize the surface of the silicon substrate 11. This thermal oxidation is performed at 1,050° C., 1,333 Pa, a hydrogen (H2) flow rate of 1 L/min, and an oxygen (O₂) flow rate of 19 L/min by a rapid thermal annealing apparatus using lamp heating. Thus, a silicon oxide film 13 having a thickness of 5-8 nm is formed in the I/O transistor formation region 1A, the LP transistor formation region 1B, and the HP transistor formation region 1C.

As shown in FIG. 1C, a resist pattern 14, which has an opening that exposes the surface of the silicon substrate 11 in the LP transistor formation region 1B, is formed on the silicon oxide film 13 by using photolithography and etching techniques. Then, the silicon oxide film 13 in the LP transistor formation region 1B is etched away by using the resist pattern 14 as a mask.

As shown in FIG. 1D, after the resist pattern 14 has been removed, thermal oxidation is performed to form a silicon oxide film 15 having a thickness of 2-5 nm on the surface of the silicon substrate 11 in the LP transistor formation region 1B. This thermal oxidation is performed at 1,050° C., 1,333 Pa, an H₂ flow rate of 1 L/min, and an O₂ flow rate of 19 L/min by a rapid thermal annealing apparatus using lamp heating.

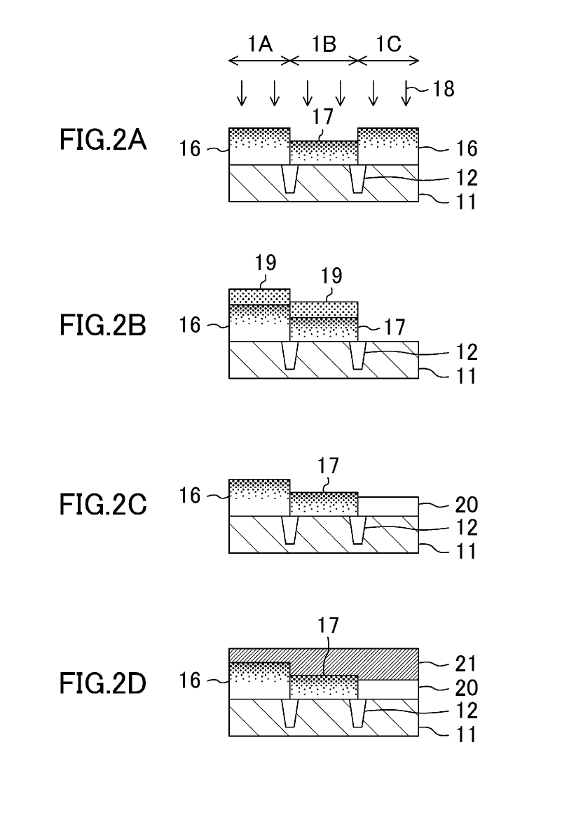

As shown in FIG. 2A, plasma nitridation 18 is performed on the silicon oxide films 13, 15 by using pulsed plasma. This plasma nitridation 18 is performed for 180 seconds at radio frequency (RF) power of 2,000W, 2.67 Pa, and a nitrogen (N₂) flow rate of 5 L/min. At this time, the silicon oxide films 13, 15 are nitrided from their top surfaces, whereby a silicon oxynitride film 16 is formed in the I/O transistor formation region 1A and the HP transistor formation region 1C, and a silicon oxynitride film 17 is formed in the LP transistor formation region 1B. Note that thermal nitridation using a gas of nitrogen monoxide, nitrogen dioxide, or ammonia may be performed instead of the plasma nitridation.

As shown in FIG. 2B, a resist pattern 19 is formed which has an opening that exposes the surface of the silicon substrate 11 in the HP transistor formation region 1C. Then, the silicon oxynitride film 16 in the HP transistor formation region 1C is etched away by using the resist pattern 19 as a mask.

As shown in FIG. 2C, after the resist pattern 19 has been removed, thermal oxidation is performed to form a silicon oxide film 20 having a thickness of 0.5-2 nm on the surface of the silicon substrate 11 in the HP transistor formation region 1C. This thermal oxidation is performed at 800° C., 400 Pa, and an O₂ flow rate of 20 L/min by a rapid thermal annealing apparatus using lamp heating.

As shown in FIG. 2D, gate polysilicon is grown on the silicon oxynitride films 16, 17 and the silicon oxide film 20 to form a gate polysilicon electrode 21.

As described above, according to the present embodiment, a semiconductor device is fabricated in which the thinnest one of the gate insulating films is comprised of silicon oxide, and the gate insulating films other than the thinnest one are comprised of silicon oxynitride, the semiconductor device including the gate insulating films having two or more different thicknesses on the same semiconductor substrate.

Thus, the thinnest gate insulating film of the HP transistor in the core section (the HP transistor formation region) is comprised of silicon oxide that has not been subjected to plasma nitridation. This can reduce or prevent an increase in equivalent oxide thickness and generation of defects in the core section due to nitrogen that reaches the interface between the silicon oxide film and the semiconductor substrate, whereby the performance of the HP transistor is not degraded. Moreover, since the gate insulating film of the HP transistor in the core section is formed after performing plasma nitridation on the gate insulating films of the I/O section (the I/O transistor formation region) and the low power section (the LP transistor formation region), a large amount of nitrogen can be introduced by the plasma nitridation into the thicker gate insulating films in the I/O section and the low power section without affecting the thinnest gate insulating film of the HP transistor. As a result, in the I/O section and the low power section, the equivalent oxide thickness of the gate insulating film can be reduced while increasing the dielectric constant and the physical thickness of the gate insulating film, whereby an increased gate breakdown voltage and a reduced gate leakage current can be achieved. Thus, high speed performance of the HP transistor in the core section can be ensured while achieving an increased gate breakdown voltage and a reduced gate leakage current in the I/O section and the low power section. Moreover, in the HP transistor in the core section, an ultrathin gate insulating film having a thickness of 0.5-2 nm can be obtained only by the silicon oxide film without performing the plasma nitridation. This enables the HP transistor in the core section to have a gate insulating film as thin as 1 nm or less so as to meet the need for a higher operating speed of the HP transistor.

### Second Embodiment

A semiconductor device and a manufacturing method thereof according to a second example embodiment of the present invention will be described with reference to the accompanying drawings.

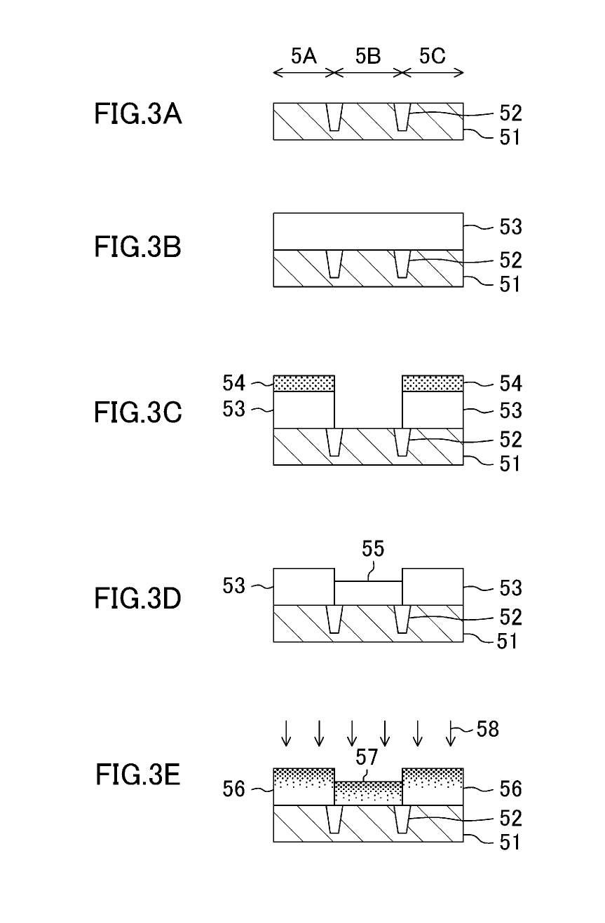

As shown in FIG. 3A, an element isolation region 52 is first formed in a silicon substrate 51 to define regions on the silicon substrate 51, thereby forming an I/O transistor formation region 5A, an LP transistor formation region 5B, and an HP transistor formation region 5C.

As shown in FIG. 3B, the silicon substrate 51 is then subjected to thermal oxidation to oxidize the surface of the silicon substrate 51. This thermal oxidation is performed at 1,050° C., 1,333 Pa, an H₂ flow rate of 1 L/min, and an O₂ flow rate of 19 L/min by a rapid thermal annealing apparatus using lamp heating. Thus, a silicon oxide film 53 having a thickness of 5-8 nm is formed in the I/O transistor formation region 5A, the LP transistor formation region 5B, and the HP transistor formation region 5C.

As shown in FIG. 3C, a resist pattern 54, which has an opening that exposes the surface of the silicon substrate 51 in the LP transistor formation region 5B, is formed on the silicon oxide film 53 by using photolithography and etching techniques. Then, the silicon oxide film 53 in the LP transistor formation region 5B is etched away by using the resist pattern 54 as a mask.

As shown in FIG. 3D, after the resist pattern 54 has been removed, thermal oxidation is performed to form a silicon oxide film 55 having a thickness of 2-5 nm on the surface of the silicon substrate 51 in the LP transistor formation region 5B. This thermal oxidation is performed at 1,050° C., 1,333 Pa, an H₂ flow rate of 1 L/min, and an O₂ flow rate of 19 L/min by a rapid thermal annealing apparatus using lamp heating.

As shown in FIG. 3E, plasma nitridation 58 is performed on the silicon oxide films 53, 55 by using pulsed plasma. This plasma nitridation 58 is performed for 180 seconds at RF power of 2,000W, 2.67 Pa, and a N₂ flow rate of 5 L/min. At this time, the silicon oxide films 53, 55 are nitrided from their top surfaces, whereby a silicon oxynitride film 56 is formed in the I/O transistor formation region 5A and the HP transistor formation region 5C, and a silicon oxynitride film 57 is formed in the LP transistor formation region 5B. Note that thermal nitridation using a gas of nitrogen monoxide, nitrogen dioxide, or ammonia may be performed instead of the plasma nitridation.

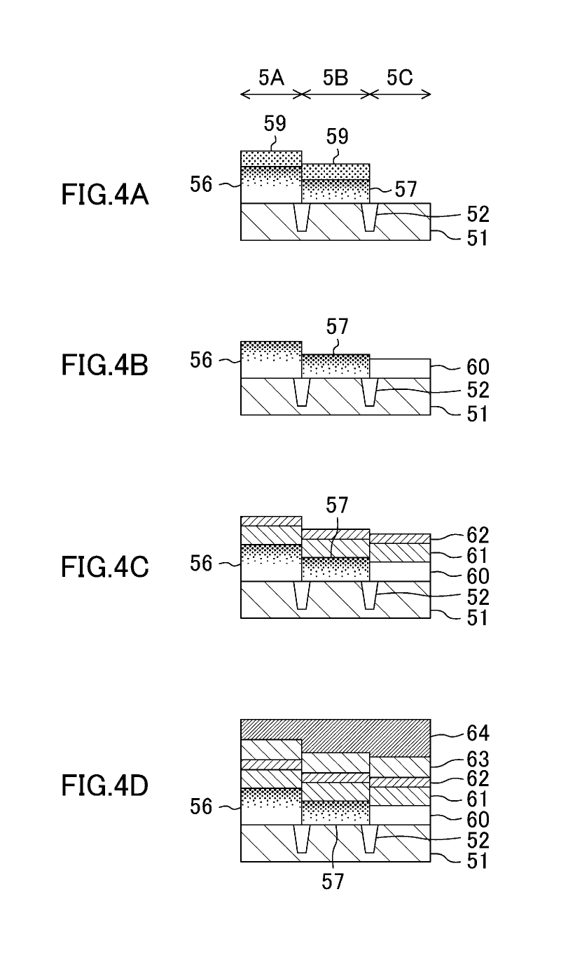

As shown in FIG. 4A, a resist pattern 59 is formed which has an opening that exposes the surface of the silicon substrate 51 in the HP transistor formation region 5C. Then, the silicon oxynitride film 56 in the HP transistor formation region 5C is etched away by using the resist pattern 59 as a mask.

As shown in FIG. 4B, after the resist pattern 59 has been removed, thermal oxidation is performed to form a silicon oxide film 60 having a thickness of 0.5-2 nm on the surface of the silicon substrate 11 in the HP transistor formation region 1C. This thermal oxidation is performed at 800° C., 400 Pa, and an O₂ flow rate of 20 L/min by a rapid thermal annealing apparatus using lamp heating.

As shown in FIG. 4C, a Hf0₂ film 61 having a thickness of 1-3 nm, which is an insulating film having a higher dielectric constant than the silicon oxide film, is formed on the silicon oxynitride films 56, 57 and the silicon oxide film 60 by an atomic layer deposition (ALD) method. Note that a metal oxide film comprised of aluminum oxide, lanthanum oxide, hafnium oxide, or zirconium oxide, or a metal silicate film comprised of aluminum silicate, lanthanum silicate, hafnium silicate, or zirconium silicate may be used as the insulating film having a higher dielectric constant than the silicon oxide film, and such a metal oxide film or a metal silicate film can be formed by a physical vapor deposition (PVD) method or a chemical vapor deposition (CVD) method. Then, an Al₂O₃ film 62 having a thickness of 0.1-1 nm is formed by a PVD method as a cap film for reducing the threshold voltage. Note that a film of ZrO₂, hafnium silicate, or zirconium silicate can be used as the insulating film having a higher dielectric constant than the silicon oxide film. An La₂O₃ film may be used as the cap film.

In the present embodiment, a film including the metal oxide film or the metal silicate film having a higher dielectric constant than the silicon oxide film is used as the gate insulating film for the following reason. The equivalent oxide thickness of an insulating film having a high dielectric constant such as the HfO₂ film 61 hardly increases even if the physical thickness thereof is increased. Thus, the gate leakage current can be reduced while maintaining high speed performance of the transistor.

Typically, forming the gate insulating film only from a metal oxide film such as the HfO₂ film 61 causes many defects at the interface with the silicon substrate, thereby degrading the transistor performance. Thus, it is desirable to use a stacked structure of the metal oxide film and a silicon oxide film or a silicon oxynitride film. In the present embodiment, a stacked structure (a first stacked film) of the HfO₂ film 61 and the silicon oxide film 60, and a stacked structure (a second stacked film) of the HfO₂ film 61 and the silicon oxynitride film 56 are used as an example. Note that the cap film is formed in order to obtain a lower threshold value. The HfO₂ film 61 may be omitted in the I/O transistor formation region 1A and the LP transistor formation region 1B.

As shown in FIG. 4D, a TiN film 63 having a thickness of 5-15 nm is formed as a metal gate electrode on the Al₂O₃ film 62 by a PVD method. Then, gate polysilicon is grown on the TiN film 63 to form a gate polysilicon electrode 64.

In the case where a metal oxide film such as the HfO₂ film 61 is used as the gate insulating film as described above, the threshold value is fixed and cannot be reduced due to Fermi level pinning if the gate polysilicon electrode 64 is used as an electrode in direct contact with the gate insulating film. Thus, in this case, a metal gate electrode comprised of the TiN film 63 etc. is used as the electrode in direct contact with the gate insulating film.

As described above, according to the present embodiment, a semiconductor device is fabricated in which the thinnest one of the gate insulating films is comprised of silicon oxide, and the gate insulating films other than the thinnest one are comprised of silicon oxynitride, the semiconductor device including the gate insulating films having two or more different thicknesses on the same semiconductor substrate.

Thus, the thinnest gate insulating film of the HP transistor in the core section (the HP transistor formation region) is comprised of a stacked film of a silicon oxide film that has not been subjected to plasma nitridation and an insulating film having a higher dielectric constant than the silicon oxide film. This can reduce or prevent an increase in equivalent oxide thickness and generation of defects in the core section due to nitrogen that reaches the interface between the silicon oxide film and the semiconductor substrate, whereby the performance of the HP transistor is not degraded. Moreover, since the silicon oxide film that forms the gate insulating film of the HP transistor in the core section is formed after forming the silicon oxynitride films that form the gate insulating films of the I/O section (the I/O transistor formation region) and the low power section (the LP transistor formation region) by plasma nitridation, a large amount of nitrogen can be introduced by the plasma nitridation into the thicker gate insulating films in the I/O section and the low power section without affecting the thinnest gate insulating film of the HP transistor. As a result, in the I/O section and the low power section, the equivalent oxide thickness of the gate insulating film can be reduced while increasing the dielectric constant and the physical thickness of the gate insulating film, whereby an increased gate breakdown voltage and a reduced gate leakage current can be achieved. Thus, high speed performance of the HP transistor in the core section can be ensured while achieving an increased gate breakdown voltage and a reduced gate leakage current in the I/O section and the low power section. Moreover, in the HP transistor in the core section, an ultrathin silicon oxide film having a thickness of 0.5-2 nm and forming the gate insulating film can be obtained without performing plasma nitridation. This enables the HP transistor in the core section to have a gate insulating film as thin as 1 nm or less so as to meet the need for a higher operating speed of the HP transistor.

In the cap film such as the Al₂O₃ film 62, the threshold value is modified by diffusing the metal oxide film or the metal silicate film and forming a dipole at the interface with the silicon oxide film. However, if there is the silicon oxynitride film rather than the silicon oxide film below the metal oxide film or the metal silicate film, nitrogen is blocked, and the threshold value cannot be significantly changed. Thus, it is desired that the HP transistor in the core section for which a low threshold value is required have a stacked structure of the silicon oxide film and the metal oxide film or the metal silicate film.

Note that the first and second embodiments are described with respect to an example in which the gate insulating film in the I/O transistor formation region 1A, 5A is thicker than the gate insulating film in the LP transistor formation region 1B, 5B. However, the gate insulating film in the I/O transistor formation region 1A, 5A may be made to have the same thickness as the gate insulating film in the LP transistor formation region 1B, 5B by adjusting a method of introducing nitrogen, as long as the balance is maintained between the gate breakdown voltages in the I/O transistor formation region 1A, 5A and the LP transistor formation region 1B, 5B, and the transistor performance in the HP transistor formation region 1C, 5C. In this case, as in the above embodiments, the step of removing the silicon oxide film in the LP transistor formation region 1B, 5B may be replaced with the step of removing the silicon oxide film in the I/O transistor formation region 1A, 5A.

As described above, the present invention is useful for semiconductor devices structured to have gate insulating films having two or more different thickness on the same semiconductor substrate, and manufacturing methods thereof

What is claimed is:

1. A semiconductor device, comprising:
a plurality of gate insulating films formed on a semiconductor substrate, wherein
one of the plurality of gate insulating films having a smallest thickness is a first stacked film that is formed by sequentially stacking, from bottom to top, a silicon oxide film and an insulating film having a higher dielectric constant than the silicon oxide film, and
each of the plurality of gate insulating films other than the one having the smallest thickness is a second stacked film formed by sequentially stacking, from bottom to top, a silicon oxynitride film and an insulating film having a higher dielectric constant than the silicon oxide film and the silicon oxynitride film, the semiconductor device further comprising:
a metal gate electrode formed on the first stacked film and the second stacked film.

2. The semiconductor device of claim 1, further comprising:
a cap film formed between the first and second stacked films and the metal gate electrode.

3. The semiconductor device of claim 1, further comprising:
a polysilicon electrode formed on the metal gate electrode.

4. The semiconductor device of claim 1, wherein
the insulating film having the higher dielectric constant than the silicon oxide film is a metal oxide film comprised of aluminum oxide, lanthanum oxide, hafnium oxide, or zirconium oxide, or a metal silicate film comprised of aluminum silicate, lanthanum silicate, hafnium silicate, or zirconium silicate.

5. The semiconductor device of claim 1, wherein
the semiconductor substrate is divided into a first semiconductor region where a high performance transistor is formed, a second semiconductor region where an I/O transistor is formed, and a third semiconductor region where a low power transistor is formed,
the plurality of gate insulating films are three gate insulating films corresponding to the first to third semiconductor regions,
of the three gate insulating films, the gate insulating film corresponding to the first semiconductor region has a smaller thickness than the gate insulating film corresponding to the second semiconductor region and the gate insulating film corresponding to the third semiconductor region, and
the gate insulating film corresponding to the second semiconductor region has a thickness equal to or larger than that of the gate insulating film corresponding to the third semiconductor region.

6. A method for manufacturing a semiconductor device, comprising the steps of:
(a) forming a plurality of silicon oxide films on a semiconductor substrate;
(b) introducing nitrogen into the plurality of silicon oxide films to form a plurality of silicon oxynitride films;
(c) removing one of the plurality of silicon oxynitride films having a smallest thickness;
(d) forming a silicon oxide film in a portion where the silicon oxynitride film having the smallest thickness has been removed in the step (c);
(e) forming an insulating film having a higher dielectric constant than the silicon oxide films and the silicon oxynitride films, on each of the plurality of silicon oxynitride films remaining after removing the silicon oxynitride film having the smallest thickness, and on the silicon oxide film formed in the step (d); and
(f) forming a metal gate electrode on the insulating film having the higher dielectric constant than the silicon oxide films and the silicon oxynitride films.

7. The method of claim 6, further comprising the step of:
(g) forming a polysilicon electrode on the metal gate electrode.

8. The method of claim 6, wherein
in the step (b), the nitrogen is introduced by plasma nitridation, or thermal nitridation using a gas of nitrogen monoxide, nitrogen dioxide, or ammonia.

9. The method of claim 6, wherein
in the step (e), the insulating film having the higher dielectric constant than the silicon oxide film is formed by an ALD method, a CVD method, or a PVD method.
